(19) United States
(12) Patent Application Publication
(10) Pub. No.: US 2011/0073998 A1
(43) Pub. Date: Mar. 31, 2011

(54) Adhesion Promotion Layer For A Semiconductor Device

(75) Inventor: Bo-Jiun Lin, Jhubei City (TW)

(73) Assignee: TAIWAN SEMICONDUCTOR MANUFACTURING COMPANY, LTD., Hsin-Chu (TW)

(21) Appl. No.: 12/569,531

(22) Filed: Sep. 29, 2009

(51) Int. Cl. H01L 23/00; H01L 21/31; H01L 21/306

(52) U.S. Cl. 257/639; 257/643; 257/640; 438/763; 438/703; 257/E23.002; 257/E21.24; 257/E21.215

(57) ABSTRACT

Embodiments of semiconductor devices are provided. In one embodiment, the semiconductor device includes a substrate, an etch stop layer formed on the substrate, an adhesion promotion layer formed directly on the etch stop layer, and a dielectric layer formed directly on the adhesion promotion layer. The etch stop layer may include silicon, carbon, and nitrogen. The dielectric layer may include silicon, oxygen, and carbon. The adhesion promotion layer may include carbon, oxygen, and nitrogen. An example of an adhesion promotion layer includes polyimide.

### BACKGROUND

The semiconductor integrated circuit (IC) industry has experienced rapid growth. In the course of IC evolution, functional density has generally increased while feature size has decreased. This scaling down process generally provides benefits by increasing production efficiency and lowering associated costs. However, as technology nodes decrease, challenges arise including those with the materials selected to be used in the processes. For example, challenges providing appropriate adhesion between one or more layers or features of a semiconductor device. Decreased adhesion strength may occur at interfaces of the semiconductor device which can lead to defects such as, peeling or delamination.

Accordingly, what is needed is a semiconductor device with improved adhesion between layers and/or features.

### SUMMARY

A semiconductor device is provided including, in an embodiment, a substrate; an etch stop layer formed on the substrate; an adhesion promotion layer formed directly on the etch stop layer; and a dielectric layer formed directly on the adhesion promotion layer. In one embodiment, the adhesion promotion layer includes polyimide.

In one embodiment, a semiconductor device that includes a substrate; an etch stop layer formed on the substrate; an adhesion promotion layer formed directly on the etch stop layer; and a dielectric layer formed directly on the adhesion promotion layer. The adhesion promotion layer includes carbon, oxygen, and nitrogen.

Methods for forming semiconductor devices are also provided. In one embodiment, a method of fabricating a semiconductor device includes providing a semiconductor substrate. A first layer is formed on the substrate. The first layer includes silicon, carbon, and nitrogen. An adhesion promotion layer is formed on the first layer. In forming the adhesion promotion layer, a first interface is formed between the first layer and the adhesion promotion layer. The adhesion promotion layer includes carbon, oxygen, and nitrogen. A dielectric layer is formed on the adhesion promotion layer. A second interface is formed between the adhesion promotion layer and the dielectric layer. The dielectric layer includes silicon, carbon, and oxygen.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a cross-sectional view illustrating an embodiment of a semiconductor device according to the prior art.

FIG. 2 is a cross-sectional view illustrating an embodiment of a semiconductor device including an adhesion promotion layer.

FIG. 3 is a cross-sectional view illustrating an embodiment of a portion of a semiconductor device including an adhesion promotion layer.

FIG. 4 is a flow chart illustrating an embodiment of a method of forming a semiconductor device including an adhesion promotion layer.

FIG. 5 is a cross-sectional view of an embodiment of a device used in an experimental embodiment.

FIG. 6 is a graphical representation of results of a stress test including the experimental embodiment of FIG. 5.

### DETAILED DESCRIPTION

The present disclosure relates generally to semiconductor (e.g., integrated circuit) devices, and more particularly, to an adhesion promotion layer of a semiconductor device.

It is understood that the following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

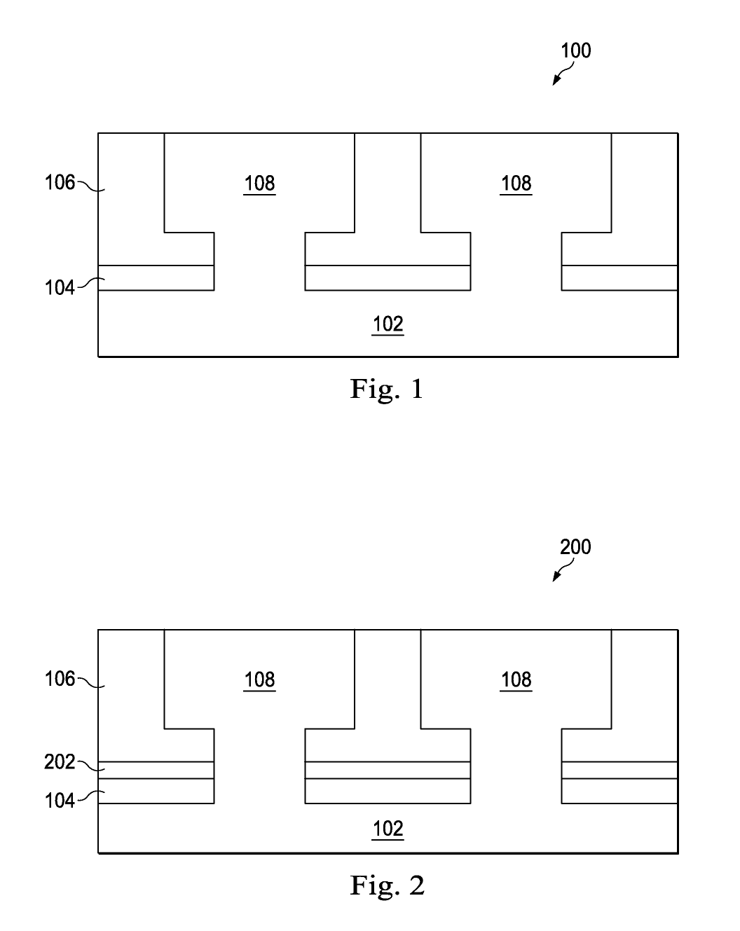

With reference to FIG. 1, illustrated is a semiconductor device 100 including a plurality of dual damascene structures 108. The dual damascene structures 108 are formed on a substrate 102, which may be any typical semiconductor substrate and include any plurality of layers or features. An etch stop layer 104 is disposed on the substrate 102. The etch stop layer 10 may be used in the fabrication of the dual damascene structures 108 such as to provide an etching endpoint for a via hole of a dual damascene structure 108. A dielectric layer 106 is disposed on the etch stop layer 104. It is noted that the dielectric layer 106 is disposed directly on the etch stop layer 104 such that an interface between the two layers is formed. Thus, the adhesion between the dielectric layer 106 and the etch stop layer 104 is determined by the intrinsic property of the materials of the dielectric layer 106 and the etch stop layer 104 themselves.

The semiconductor device 100 may be illustrative of certain disadvantages found in embodiments provided by the prior art. For example, the semiconductor device 100 may exhibit a low adhesion strength at the interface between the dielectric layer 106 and the etch stop layer 104. This low adhesion strength may contribute to defects such as post-chemical mechanical polish (CMP) peeling, delamination after packaging, and/or other defects.

Referring now to FIG. 2, illustrated is a cross-sectional view of a semiconductor device 200. The semiconductor device 200 may include passive components such as resistors, capacitors, inductors, and/or fuses; and active components, such as P-channel field effect transistors (PFETs), N-channel field effect transistors (NFETs), metal-oxide-semiconductor field effect transistors (MOSFETs), complementary metal-oxide-semiconductor transistors (CMOSs), high voltage transistors, and/or high frequency transistors; other suitable components; and/or combinations thereof. The semiconductor device 200 includes a substrate 102. The substrate 102 may include an elementary semiconductor including silicon and/or germanium in crystal; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; combinations thereof; or other suitable substrate materials. In embodiments, the substrate 102 may be a semiconductor on insulator (SOI) substrate, a strained substrate, and/or include other features known in the art. The semiconductor substrate 102 includes a plurality features or layers formed thereon, including, for example, doped regions, active devices (e.g., gate structures), isolation regions, interconnect structures (e.g., metal lines, vias, contacts), and like features. It is understood that the substrate 102 may include features formed using CMOS technology processing known in the art, and thus processes are not described in detail herein.

A plurality of layers and/or features are formed on the substrate 102 including an etch stop layer 104, an adhesion promotion layer 202, a dielectric layer 106, and a plurality of dual damascene structures 108. In embodiments, one or more of these layers may be omitted, additional layers may be provided, and/or the layers may be provided in a different sequence. The etch stop layer 104 may include SiC, SiOC, SiN, SiON, SiCN, and/or other suitable materials. In an embodiment, the etch stop layer 104 includes silicon, carbon, and/or nitrogen. The dielectric layer 106 may be an interlayer dielectric layer (ILD). In an embodiment, the dielectric layer 106 includes a low-k dielectric material. Examples of low-k dielectric material include fluorinated silica glass (FSG), doped (e.g., carbon, fluorine) silicon oxide, Black Diamond® (Applied Materials of Santa Clara, Calif.), Xerogel, Aerogel, amorphous fluorinated carbon, Parylene, BCB (bis-benzocyclobutenes), SiLK (Dow Chemical, Midland, Mich.), hydrogen silsesquioxane (HSQ), methyl silsesqioxane (MSQ), and/or combinations thereof. In an embodiment, the dielectric layer 106 includes silicon, oxygen, carbon, and/or hydrogen. The dielectric layer 106 and/or the etch stop layer 104 may be formed by any suitable process to any suitable thickness, including by chemical vapor deposition (CVD), high density plasma CVD, spin-on processing, sputtering, and/or other suitable methods. The dielectric layer 106 may further include a multilayer structure comprising multiple dielectric materials. The dual damascene structure 108 may include any suitable conductive material (e.g., copper). The dual damascene structure 108 may include multiple layers including, for example, liner or barrier layers. The dual damascene may be formed using any suitable process such as, etching, plating, deposition, chemical mechanical polishing (CMP), and/or other suitable processes.

The adhesion promotion layer 202 interposes the etch stop layer 104 and the dielectric layer 106. The adhesion promotion layer 202 includes an upper surface which has an interface to the dielectric layer 106 and a lower surface which has an interface to the etch stop layer 104. The adhesion promotion layer 202 includes carbon, oxygen, nitrogen, and/or hydrogen. In an embodiment, the adhesion promotion layer 202 includes polyimide. Polyimide may be represented as:

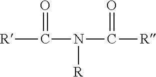

(R, R′, R″ may be any composition including, for example, carbon atoms of an aromatic ring). In an embodiment, the adhesion promotion layer 202 includes a dilute polyimide. By way of example and not intending to be limiting, the polyimide may include 20 times by volume of a solvent.

The adhesion promotion layer 202 may be of any suitable thickness. In an embodiment, the thickness of the adhesion promotion layer 202 is below approximately 100 A. In other embodiments, the adhesion promotion layer 202 is on the order of hundreds of angstroms or less (e.g., <1000 A). In still other embodiments, the adhesion promotion layer 202 may be several microns in thickness (e.g., 10 μm). The adhesion promotion layer 202 may be deposited on the substrate 102 using a spin-on method and/or other suitable method.

FIG. 2 illustrated an embodiment of a semiconductor device including an adhesion promotion layer associated with a dual damascene structure. Numerous other embodiments of semiconductor devices and portions thereof may benefit from an adhesion promotion layer including those features that may be formed using a dielectric layer and an etch stop layer. Example features include isolation structures (e.g., shallow trench isolation structures); interconnect structures, and/or other suitable features.

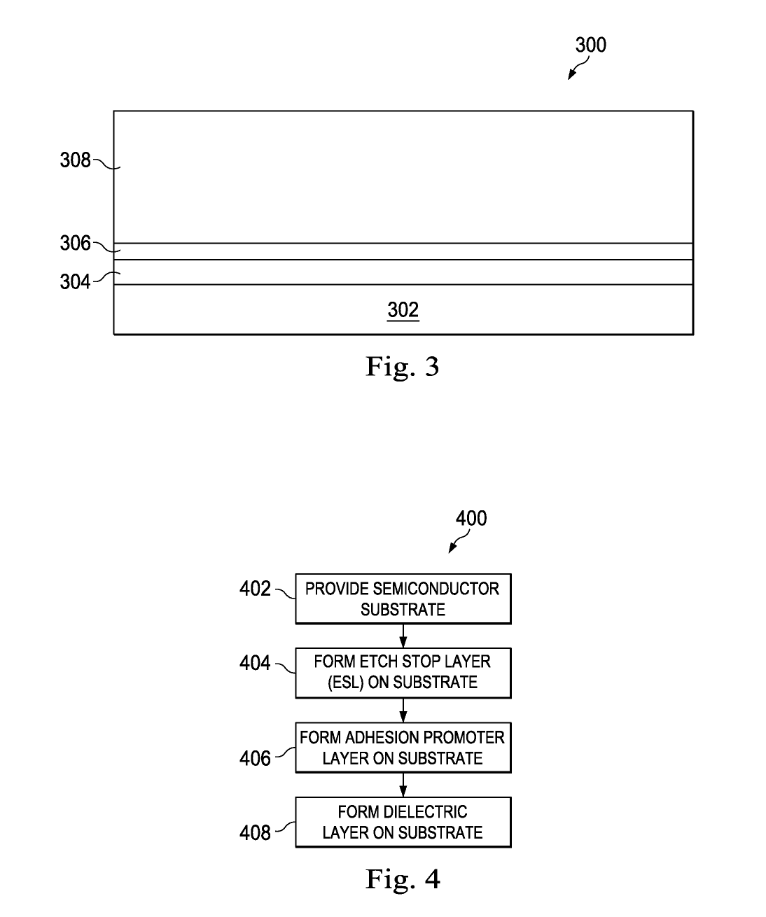

FIG. 3 illustrates a semiconductor device 300, or portion thereof. The semiconductor device 300 may include passive components such as resistors, capacitors, inductors, and/or fuses; and active components, such as P-channel field effect transistors (PFETs), N-channel field effect transistors (NFETs), metal-oxide-semiconductor field effect transistors (MOSFETs), complementary metal-oxide-semiconductor (CMOS) transistors, high voltage transistors, and/or high frequency transistors; other suitable components; and/or combinations thereof. The semiconductor device 300 includes a substrate 302. The substrate 302 may include an elementary semiconductor including silicon and/or germanium in crystal; a compound semiconductor including silicon carbide, gallium arsenic, gallium phosphide, indium phosphide, indium arsenide, and/or indium antimonide; an alloy semiconductor including SiGe, GaAsP, AlInAs, AIGaAs, GaInAs, GaInP, and/or GaInAsP; combinations thereof; or other suitable substrate materials. In embodiments, the substrate 302 may be a semiconductor on insulator (SOI) substrate, a strained substrate, and/or include other features known in the art. The semiconductor substrate 302 includes a plurality features or layers formed thereon, including, for example, doped regions, active devices (e.g., gate structures), isolation regions, interconnect structures (e.g., metal lines, vias, contacts), and like features. It is understood that the substrate 302 may include features formed using CMOS technology processing known in the art, and thus processes are not described in detail herein.

A plurality of layers (features) is formed on the substrate 302 including a first layer 304, an adhesion promotion layer 302, and a dielectric layer 308. In embodiments, one or more of these layers may be omitted, additional layers may be provided and/or the layers may be provided in a different sequence. In an embodiment, the first layer 304 includes silicon, carbon, and nitrogen. The first layer 304 may be an etch stop layer. Example compositions of the first layer 304 include SiC, SiOC, SiN, SiON, SiCN, and/or other suitable materials.

The dielectric layer 308 may include silicon, oxygen, carbon, and/or hydrogen. In an embodiment, the dielectric layer 308 includes a low-k dielectric. Examples of low-k dielectric material include fluorinated silica glass (FSG), doped (e.g., carbon) silicon oxide, Black Diamond® (Applied Materials of Santa Clara, Calif.), Xerogel, Aerogel, amorphous fluorinated carbon, Parylene, BCB (bis-benzocyclobutenes), SiLK (Dow Chemical, Midland, Mich.), HSQ, MSQ, and/or combinations thereof. The dielectric layer 308 and/or the etch stop layer 304 may be formed by any suitable process to any suitable thickness, including by chemical vapor deposition (CVD), high density plasma CVD, spin-on processing, sputtering, and/or other suitable methods. The dielectric layer 308 may further include a multilayer structure comprising multiple dielectric materials.

The adhesion promotion layer 306 interposes the first layer 304 and the dielectric layer 308. The adhesion promotion layer 306 includes an upper surface which has an interface to the dielectric layer 308 and a lower surface which has an interface to the first layer 304. The adhesion promotion layer 306 includes carbon, oxygen, nitrogen, and/or hydrogen. In an embodiment, the adhesion promotion layer 202 includes polyimide. Polyimide may be provided as:

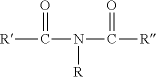

(R, R′, R″ may be any composition including, for example, carbon atoms of an aromatic ring). In an embodiment, the adhesion promotion layer 306 includes a dilute polyimide. By way of example and not intending to be limiting, the polyimide may include 20 times by volume of a solvent. In an embodiment, the adhesion promotion layer 306 includes one or more elements (e.g., oxygen, carbon) in common with the dielectric layer 308 and or one more elements (e.g., carbon, nitrogen) in common with the first layer 304.

The adhesion promotion layer 306 may be of any suitable thickness. In an embodiment, the thickness of the adhesion promotion layer 306 is below approximately 100 A. In other embodiments, the adhesion promotion layer 306 is on the order of hundreds of angstroms of less (e.g., <1000 A). In still other embodiments, the adhesion promotion layer 306 may be several microns in thickness (e.g., 10 um). The adhesion promotion layer 306 may be deposited on the substrate 302 using a spin-on method and/or other suitable method.

Referring now to FIG. 4, illustrated is a method 400 of forming a semiconductor device. It is understood that additional steps can be provided before, during, and after the method 400, and some of the steps described below can be replaced or eliminated, for additional embodiments of the method. The method 400 begins at step 402 where a substrate is provided. The substrate may be substantially similar to the substrate 102 and/or 302, described above with reference to FIGS. 2 and 3. The substrate may include any plurality of layers or features formed thereon.

The method 400 then proceeds to step 404 where an etch stop layer is formed on the substrate. The etch stop layer may be substantially similar to the etch stop layer 104 and/or the first layer 304, described above with reference to FIGS. 2 and 3. In alternative embodiments, the layer provided may provide functionality other than or in addition to an etch stop and include a composition having silicon, oxygen, and carbon. The layer may include silicon, oxygen, carbon, and/or hydrogen. The layer of step 404 may be formed through suitable methods including CVD, PVD, spin-on coating, and/or other suitable methods.

The method 400 then proceeds to step 406 where an adhesion promotion layer is formed on the substrate. In an embodiment, the adhesion promotion layer is formed directly on the etch stop layer of step 404. The adhesion promotion layer may be substantially similar to the adhesion promotion layer 202 and/or 306, described above with reference to FIGS. 2 and 3. The adhesion promotion layer may be formed by spin-on coating and/or other suitable methods.

In an embodiment of the method 400, one or more treatment processes may be formed on the adhesion promotion layer during or after its formation. The treatment process may further enhance the adhesion properties of the layer. Example treatment processes include, chemical treatments (e.g., an ammonia treatment), plasma treatment, thermal treatments, and/or other suitable treatments.

The method 400 then proceeds to step 408 where a dielectric layer is formed on the substrate. The dielectric layer may be formed directly on the adhesion promotion layer. The dielectric layer may be substantially similar to the dielectric layers 106 and/or 308, described above with reference to FIGS. 2 and 3. The dielectric layer may be formed using CVD, spin-on coating, and/or other suitable methods.

Thus, the method 400 provides for fabrication of a semiconductor device, or portion thereof, including a stack including an etch stop layer, an adhesion promotion layer, and a dielectric layer. The adhesion promotion layer may have an interface to both the etch stop layer and the dielectric layer. In an embodiment, the adhesion promotion layer includes polyimide.

Thus, one or more embodiments described herein may provide advantages such as increased adhesion between layers of a semiconductor device. Examples include increased adhesion between an etch stop layer and an adjacent dielectric layer.

### Experimental Embodiment

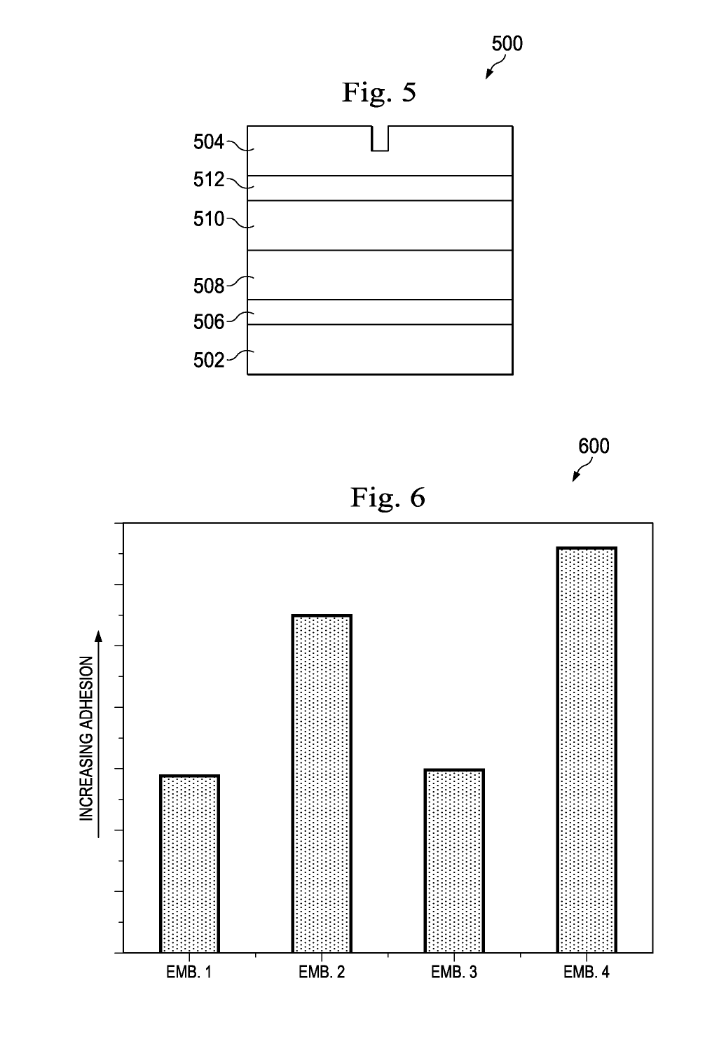

Referring now to FIGS. 5 and 6, illustrated is an experimental embodiment illustrating an increased adhesion provided by an embodiment of an adhesion promotion layer. FIG. 5 illustrates a device 500. The device 500 may be used as a test vehicle to compare various embodiments. The device 500 includes a first and second bare silicon wafer 502 and 504 (wafer 504 having a notch), a SiCN layer 506, a dielectric material layer 508, a silicon oxide layer 510, and an epoxy layer 512. In an experimental embodiment, the thickness of the SiCN layer 506 is approximately 500 A; the thickness of the low-k material layer 508 approximately 3.4 kA, and the silicon oxide layer 510 between approximately 3 kA and approximately 4 kA, though numerous other embodiments are possible.

FIG. 6 illustrates the relative results of a four-point bend test using the device of FIG. 5 and variations thereof. The graph 600 illustrates the results of using a spin-on material. The graph 600 includes Embodiment 1 which has the dielectric material layer 508 includes extra-low k dielectric (ELK) interfacing with the SiCN layer 506. Embodiment 2 illustrates the bending test result of the device 500 which has a dielectric material layer 508 that includes a carbon-doped silicon dioxide layer interfacing with the SiCN layer 506. An example of a carbon-doped silicon dioxide layer is BLACK DIAMOND (“BD”) (commercially available material from Applied Materials). Embodiment 3 illustrates the bending test of the device 500 including a dielectric material layer 508 of a spin-on material (e.g., JSR 6202 (commercially available low-k material)) interfacing with the SiCN layer 506. Embodiment 4 illustrates the bending test results of the device 500 including a dilute polyimide (PI) layer interposed between the dielectric material layer 508 and the SiCN layer 506. As is evidenced by graph 600, Embodiment 4 (the dilute PI adhesion layer) provides the highest relative adhesion strength. The adhesion may be measured by Gc (critical crack extension force) as provided by a 4-point bending test. Gc may be dependent upon the dimensions of the device 500 (e.g., thickness and width), the force applied, the positioning of the force applied (e.g., location of the four points), and/or other variables. In an embodiment, Embodiment 4 provides a Gc of approximately 7 while Embodiments 1 and 3 provide a Gc of less than 3.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
a substrate;
an etch stop layer formed on the substrate;
an adhesion promotion layer formed directly on the etch stop layer; and
a dielectric layer formed directly on the adhesion promotion layer.

2. The device of claim 1, wherein the adhesion promotion layer includes polyimide.

3. The device of claim 1, wherein the etch stop layer includes silicon, carbon, and nitrogen.

4. The device of claim 1, wherein the dielectric layer includes silicon, oxygen, and carbon.

5. The device of claim 1, wherein the adhesion promotion layer includes carbon, oxygen, and nitrogen.

6. The device of claim 1, wherein the etch stop layer includes silicon, carbon, and nitrogen, wherein the dielectric layer includes silicon, oxygen, and carbon, and wherein the adhesion promotion layer includes carbon, oxygen, and nitrogen.

7. The device of claim 1, wherein the adhesion promotion layer includes a dilute polyimide.

8. The device of claim 1, wherein the adhesion promotion layer is less than approximately 1000 A.

9. A semiconductor device, comprising:
a substrate;
an etch stop layer formed on the substrate;
an adhesion promotion layer formed directly on the etch stop layer, wherein the adhesion promotion layer includes carbon, oxygen, and nitrogen; and
a dielectric layer formed directly on the adhesion promotion layer.

10. The device of claim 9, wherein the dielectric layer includes a low-k dielectric material.

11. The device of claim 10, wherein the low-k dielectric material is selected from a group consisting of fluorinated silica glass (FSG), doped silicon oxide, Black Diamond, Xerogel, Aerogel, amorphous fluorinated carbon, Parylene, bis-benzocyclobutenes (BCB), Sil.K, hydrogen silsesquioxane (HSQ), methyl silsesqioxane (MSQ), and/or combinations thereof.

12. The device of claim 9, wherein the etch stop layer includes a material selected from a group consisting of SiC, SiOC, SiN, SiON, and SiCN.

13. The device of claim 9, wherein the adhesion promotion layer further includes hydrogen.

14. The device of claim 9, wherein the adhesion promotion layer is a polyimide.

15. A method of fabricating a semiconductor device, comprising:
providing a semiconductor substrate;
forming a first layer on the substrate, wherein the first layer includes silicon, carbon, and nitrogen;
forming an adhesion promotion layer on the first layer, wherein a first interface is formed between the first layer and the adhesion promotion layer, and wherein the adhesion promotion layer includes carbon, oxygen, and nitrogen; and
forming a dielectric layer on the adhesion promotion layer, wherein a second interlace is Formed between the adhesion promotion layer and the dielectric layer, and wherein the dielectric layer includes silicon, carbon, and oxygen.

16. The method of claim 15, wherein the forming the adhesion promotion layer includes spinning on a polyimide material.

17. The method of claim 16, wherein the polyimide material includes a dilute polyimide.

18. The method of claim 15, further comprising:
etching the dielectric layer to form an interconnect structure, wherein an etching endpoint is determined by the first layer.

19. The method of claim 15, wherein forming the adhesion promotion layer on the first layer includes forming the adhesion promotion layer to a thickness of less than approximately 100 Angstroms.

20. The method of claim 15, further comprising:
treating the adhesion promotion layer prior to forming the dielectric layer, wherein the treating includes at least one of a thermal treatment, a plasma treatment, and a chemical treatment.
